(19) United States
(12) Patent Application Publication
(10) Pub. No.: US 2023/0098393 A1
(43) Pub. Date: Mar. 30, 2023

(54) LEAD FRAME AND PACKAGING METHOD

(71) Applicant: Richtek Technology Corporation, Zhubei City (TW)

(72) Inventors: Hao-Lin Yen, Taoyuan (TW); Heng-Chi Huang, Hsinchu (TW); Yong-Zhong Hu, Hsinchu (TW)

(21) Appl. No.: 17/847,231

(22) Filed: Jun. 23, 2022

(30) Foreign Application Priority Data
Sep. 24, 2021 (TW) 110135504

(51) Int. Cl. H01L 23/495; H01L 23/31; H01L 21/48; H01L 21/56

(52) U.S. Cl. CPC H01L 23/49544; H01L 23/3107; H01L 23/49503; H01L 23/4952; H01L 23/49568; H01L 23/49575; H01L 21/4825; H01L 21/4842; H01L 21/565

(57) ABSTRACT

A lead frame includes: at least one ductile structure, including a bond area, a die paddle, or a lead finger; and at least one sacrificial structure, connected between a corresponding ductile structure and a corresponding near portion in the lead frame, wherein the near portion is a portion of the lead frame close to the ductile structure.

### CROSS REFERENCE

The present invention claims priority to TW 110135504 filed on Sep. 24, 2021.

### BACKGROUND OF THE INVENTION

### Field of Invention

The present invention relates to a lead frame, especially a lead frame with a sacrificial structure to provide a temporary strengthening capability for lessening internal deformation of the lead frame during its manufacturing process.

### Description of Related Art

Along the trend of increasing package size, the bond area, die paddle, and lead finger in the lead frame all become larger in size. Referring to FIG. 1, due to signal connection requirement, the internal structure in the lead frame 11 has more long extending portions which are easy to distort. When the layout of the lead frame 11 becomes complicated, the long extending portions of the internal structure in the lead frame 11 need to include curve shapes in order to leave space for other internal structures in the lead frame 11. However, such curve shape layout may cause serious distortion and deformation, to induce structural dislocation, fracture, or failure of signal transmission function. In addition, the distortion and deformation conditions may contribute to poor flatness of soldering surface on the internal structure of the lead frame 11, which may lead to desoldering or solder skip. These problems are generally not examined until the quality control stage, so that subsequent processing becomes very labor-intensive in later stage.

To eliminate the above problems, FIG. 2 shows a schematic diagram of prior art US patent publication US 20080157297, in which the chip 21 is disposed on a lead frame 23. For reducing the impact of stress, multiple sets of S-shaped buffer structures 22 are provided to absorb the difference of deformation amount between the internal and external structures in the lead frame, to reduce couple effect between the internal and external structures. In order to accommodate the S-shaped buffer structures 22 with their deformation spaces, the surrounding portion of the lead frame 23 is expanded outwardly, resulting in a large package size which can be multiple times of the usual package size; that is, its space utilization efficiency is low.

FIG. 3 shows a schematic diagram of prior art U.S. Pat. No. 9,093,486, wherein an adhesive tape 32 is attached to one side of a lead frame 31, and a stripe 33 is attached to the other side of the lead frame 31, so that the lead frame 31 is sandwiched between the adhesive tape 32 and the stripe 33; and, a portion of the lead frame 31 between the adhesive tape 32 and the stripe 33 is pre-filled with a package material 34, so as to avoid the potential deformation of the lead frame 31 during manufacturing. The adhesive tape 32 and the stripe 33 partially seal the lead frame 31, to form a semi-enclosed space for pre-filling the package material 34 over the lead frame 31 for deformation prevention. After pre-filling the package material 34 and removing the adhesive tape 32 and the stripe 33, the chip and bonding wires are disposed on the lead frame 31 with the package material 34 filled inside. Then, a new portion of the package material 34 is stacked and melted on the lead frame 31 with the chip and bonding wires, and the new stacked package material 34 is cured. However, it is difficult to have good soldering connection between the new stacked package material 34 and the pre-filled package material 34, because there may be high residual stress accumulated on the soldering interface between the new stacked and pre-filled package materials 34. The residual stress may be induced by the instantaneous phase change or the thermal expansion difference between the new stacked and pre-filled package materials 34 at two different temperatures. Further, because it is semi-enclosing, the package material may leak into the space between the lead frame 31 and the adhesive tape 32 or the space between the lead frame 31 and the stripe 33, and this space may be a critical reserved clear area for subsequent soldering or component disposition. This package material leakage may leave a package material stain on the top or bottom surface of the lead frame 31, resulting in poor surface contact quality to obsess subsequent component soldering. Or, when the temperature for curing the melted package material is too high, the solidified pre-filled package material 34 may be partially melted again, causing structure drift or deformation in the lead frame 31, and adversely affected the positioning accuracy of the lead frame 31.

The prior art U.S. Pat. No. 7,439,097 is similar to the prior art U.S. Pat. No. 9,093,486, in which a pre-filling process is also applied on the lead frame. However, as mentioned earlier, such kind of prior arts have drawbacks of poor soldering connection between the new stacked package material and the pre-filled package material, package material leakage, and structure drift or deformation caused by high temperature, which all may lead to poor reliability and poor quality of the lead frame.

In view of the problems of the prior art, the present invention provides a lead frame structure, which can greatly reduce the distortion possibility in the internal structure of the lead frame, while meeting the requirements of single package material filling process and no obvious size increase of the lead frame package.

### SUMMARY OF THE INVENTION

In one perspective, the present invention provides a lead frame to solve the aforementioned problems. The lead frame includes at least one ductile structure and at least one sacrificial structure. The ductile structure includes a bond area, a die paddle, or a lead finger. The sacrificial structure is connected between the corresponding ductile structure and a near portion of the lead frame which is close to the corresponding ductile structure, to provide a temporary strengthening structure to reduce or avoid the distortion of the ductile structure during the manufacturing process.

When the package size (form factor) becomes larger, it is often required for the bond area, the die paddle, or the lead finger in the lead frame to have a complex layout that includes a slender and curved internal structure for signal communication. Regardless whether the lead frame is cut by mechanical machining, laser cutting or chemical etching, the slender and curved internal structures of the lead frame often have weak structural strength, to induce distortion and deformation in the lead frame. The present invention provides a sacrificial structure at weaker portions in the lead frame to strengthen the structural strength (or the structural rigidity), which is one important feature of the present invention.

In one embodiment, the sacrificial structure has a half-cut state in the lead frame. The sacrificial structure in the half-cut state has a thickness less than the thickness of the lead frame (for example, less than half of the average thickness of the lead frame).

In one embodiment, the near portion in the lead frame further includes another bond area, another die paddle, or another lead finger close to the ductile structure, and in one embodiment, such another bond area, another die paddle, or another lead finger can form a strengthening structure with the present ductile structure to strength the rigidity of the present ductile structure. In one embodiment, the lead frame may further include another bond area, another die paddle, another lead finger, or a surrounding portion in the lead frame close to the present ductile structure, and in one embodiment, such another bond area, another die paddle, another lead finger, or the surrounding portion can form a strengthening structure with the present ductile structure to strength the rigidity of the present ductile structure.

The lead frame of the present invention can be used in quad flat no lead package (QFN), quad flat package (QFP), dual in-line package (DIP), small outline package (SOP), small outline transistor package (SOT), or system on integrated chip package (SOIC).

In another perspective, the present invention provides a packaging method, which includes: providing a lead frame, which includes at least one ductile structure and at least one sacrificial structure, wherein the sacrificial structure is connected between a corresponding one of the at least one ductile structure and a near portion of the lead frame, wherein the near portion is a portion of the lead frame close to the ductile structure; disposing a die or a heat dissipation element on the lead frame; providing a package material to encapsulate the lead frame and at least one of the die and the heat dissipation element on the lead frame; completely cutting off the sacrificial structure or removing a portion of the sacrificial structure from the lead frame; and cutting the package material and the lead frame to form a plurality of package structures, wherein each of the package structures includes a package material portion, a lead frame portion, and at least one of the die and the heat dissipation element.

In one embodiment, the step of encapsulating the lead frame and at least one of the die and the heat dissipation element with the package material, further includes: encapsulating the package material on one side of the lead frame, together with the die or the heat dissipation element on this side of the lead frame.

In one embodiment, the step of completely cutting off the sacrificial structure or removing a portion of the sacrificial structure from the lead frame, includes: completely cutting off the sacrificial structure or removing the portion of the sacrificial structure from the lead frame by laser cutting, chemical etching, or mechanical machining.

The objectives, technical details, features, and effects of the present invention will be better understood with regard to the detailed description of the embodiments below, with reference to the attached drawings.

### BRIEF DESCRIPTION OF THE DRAWINGS

FIGS. 1, 2, and 3 show schematic diagrams of the lead frames in the prior arts.

FIGS. 4 and 5 show schematic diagrams of the lead frames according to two embodiments of the present invention.

FIGS. 6A to 6F show schematic diagrams of the steps of a packaging method according to one embodiment of the present invention.

FIGS. 7A to 7F show schematic diagrams of the steps of a packaging method according to another embodiment of the present invention.

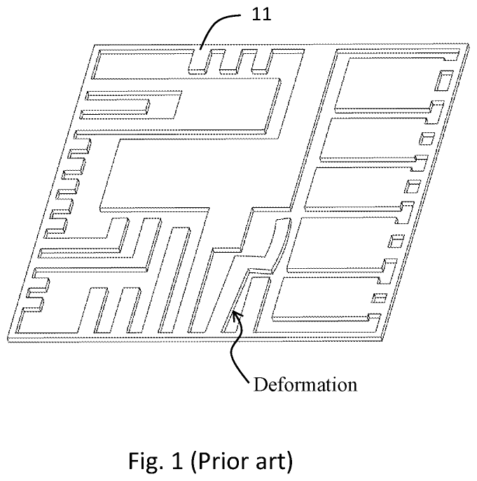

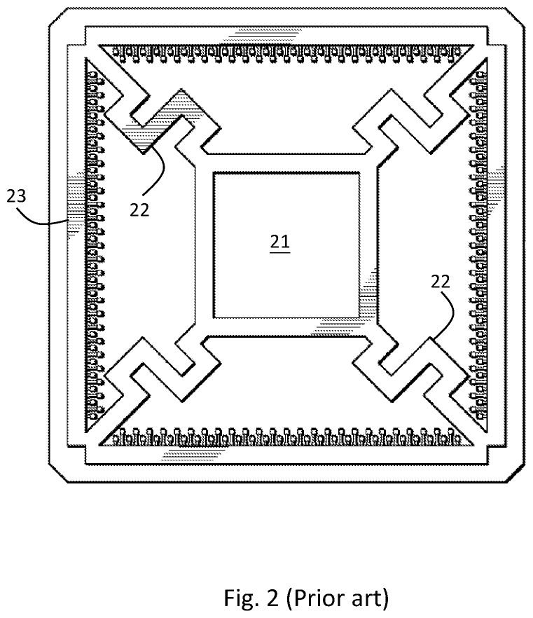

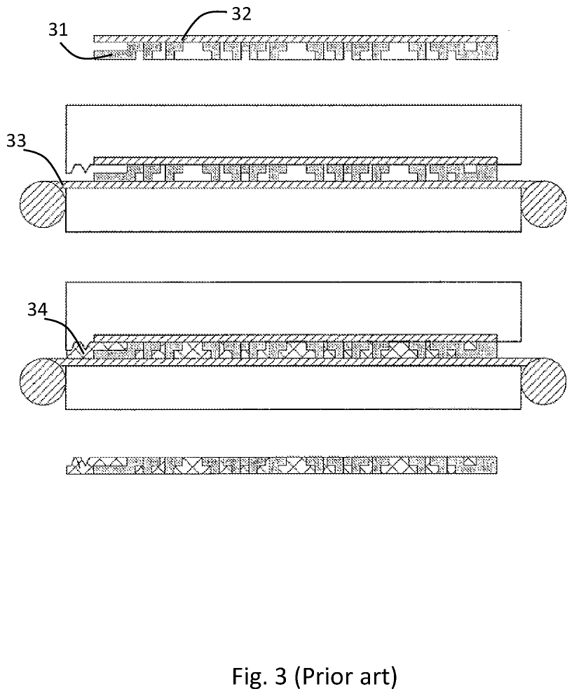

### DESCRIPTION OF THE PREFERRED EMBODIMENTS

The drawings as referred to throughout the description of the present invention are for illustration only, to show the interrelations between the components or units, but not drawn according to actual scale of sizes.

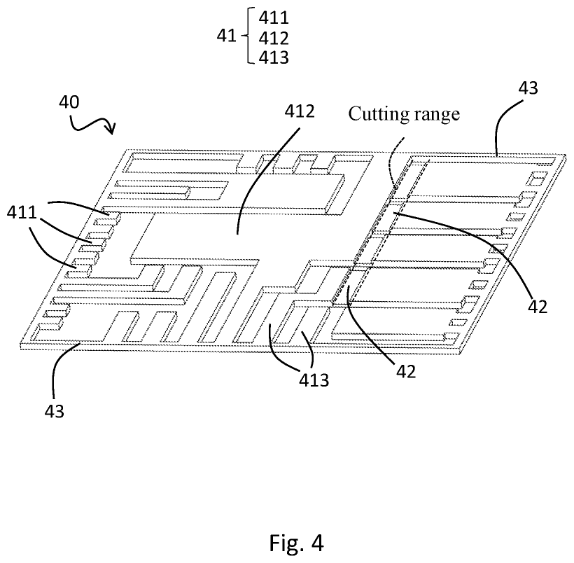

FIG. 4 shows a lead frame 40 according to one perspective of the present invention, to address the aforementioned problems. The lead frame 40 includes a ductile structure 41 and a sacrificial structure 42. The ductile structure 41 includes, for example, a bond area 411, a die paddle 412, and/or one or more lead fingers 413. It is required to maintain the ductile structure 41 at its accurate position before and after filling the package material, otherwise the subsequent processing reliability will be adversely affected. The sacrificial structure 42 is connected between the ductile structure 41 and a near portion of the lead frame 40 to provide temporary support for reducing or avoiding a distortion of the ductile structure 41 during the manufacturing process. The aforementioned near portion is a portion of the lead frame 40 near the ductile structure 41. In one embodiment, the ductile structure 41 is for disposing components in the lead frame 40 or for connection with bonding wires.

Note that, FIG. 4 is only one embodiment of the present invention for illustrative purpose; in other embodiments, it is not necessary for the ductile structure 41 to include e.g. lead fingers 413. The bond area, the die paddle and the lead fingers are typical slender structures often existing in a lead frame, so FIG. 4 shows these as examples. The accuracies of the positions of the bond area 411, the die paddle 412, and the lead fingers 413 can significantly affect subsequent manufacturing and application reliability. In various different embodiments, the slender structures in the lead frame 40 can include other kinds of slender structures besides the bond area 411, the die paddle 412, and the lead finger 413; and, the ductile structure 41 can also include an internal structure of the lead frame 40. Besides, the numbers of the bond area 411, the die paddle 412, and the lead fingers 413 are not limited the numbers shown in the drawings.

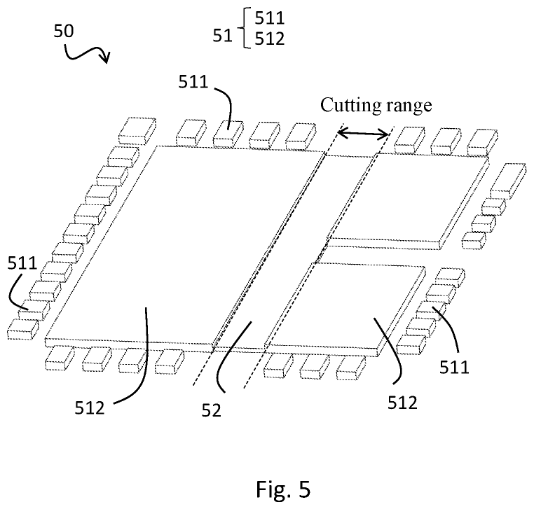

FIG. 5 shows another embodiment. The lead frame 50 in this embodiment includes a ductile structure 51 and a sacrificial structure 52, wherein the ductile structure 51 is different from the ductile structure 41 in FIG. 4. The ductile structure 51 mainly includes the bond area 511 and the die paddle 512. According to the embodiments shown in FIGS. 4 and 5, it can be understood that the ductile structures of the present invention can have different combinations of structures/components.

Referring to the lead frame 40 of FIG. 4, when the package size (form factor) becomes larger, it is often required for the bond area 411, the die paddle 412, or the lead finger 413 in the lead frame 40 to have a complex layout that includes a slender and curved internal structure for signal communication. Regardless whether the lead frame 40 is cut by mechanical machining, laser cutting or chemical etching, the slender and curved internal structures of the lead frame 40 often have weak structural strength, to induce distortion and deformation in the lead frame 40. Under the light and thin package requirement, the thickness of lead frame 40 becomes thinner, making the weak structural strength to be worse. When encapsulating the lead frame 40 with a die or a heat dissipation element (such as copper clip) thereon, the temperature change in the process from filling the package material to cooling can cause the thermal expansion state of the package material to change and result in volume change. The thermal expansion coefficients of the package material and the lead frame 40 are different, and the temperature change can cause stress on the lead frame 40 and result in the deformation of the internal structure of the lead frame 40. To solve the above problems, according to the present invention, the sacrificial structure 42 is added at weaker portions in the lead frame 40 to strengthen the structural strength (or the structural rigidity), which is one important feature of the present invention. The sacrificial structure 42 is for providing temporary strengthening effect, and after encapsulating the lead frame 40 with the die and/or the heat dissipation element thereon by the package material (at this moment, the internal structures of the lead frame 40 have been fixed by the package material), the sacrificial structure 42 can be removed from the lead frame 40. After removing the sacrificial structure 42, the temporary connections between the bond area 411, the die paddle 412, and/or the lead finger 413 formed by the sacrificial structure 42 are removed. At this moment, the ductile structure 41 has been fixed by the solidified package material and is not easily twisted or deformed.

In one embodiment, the sacrificial structure 42 has a half-cut state in the lead frame 40, that is, the sacrificial structure 42 in this half-cut state has a thickness which is less than half the thickness of other portions in the lead frame 40 (for example, half of the average thickness of the lead frame 40). Alternatively, in another embodiment, the sacrificial structure 42 may also have the same thickness as the average thickness of the lead frame 40 according to structural strength requirements for subsequent manufacturing processes. In one embodiment wherein the sacrificial structure 42 has the same thickness as other portions in the lead frame 40, the sacrificial structure 42 extends by a distance, wherein the distance is preferably less than the average thickness. This half-cut state or extended distance can form one or more fracture line in the interface between the sacrificial structure 42 with the bond area 411, the die paddle 412, or the lead finger 413. In this manner, when removing the sacrificial structure 42, the removal range of the sacrificial structure 42 (such as the dashed line shown in FIG. 4) can accurately follow the reserved fracture line to avoid damaging the bond area 411, die paddle 412, or lead finger 413. Importantly, before encapsulating the lead frame 40, the connection between the sacrificial structure 42 and the bond area 411, the die paddle 412, or the lead finger 413, can greatly improve the mechanical stability of the ductile structure 41 in the lead frame 40.

In one embodiment, the near portion of the lead frame 40 may further include another bond area 411, another die paddle 412, or another lead finger 413 close to the present ductile structure 41 in the lead frame 40, and in one embodiment, such another bond area 411, another die paddle 412, or another lead finger 413 can form a strengthening structure with the present ductile structure 41 to strength the rigidity of the present ductile structure 41. In one embodiment, the lead frame 40 further includes a surrounding portion around the lead frame 40. In this embodiment, the near portion of the lead frame 40 may further include another bond area 411, another die paddle 412, another lead finger 413, or the surrounding portion in the lead frame 40 close to the present ductile structure 41, and in one embodiment, such another bond area 411, another die paddle 412, another lead finger 413, or the surrounding portion can forma strengthening structure with the present ductile structure 41 to strength the rigidity of the present ductile structure 41.

In another perspective, the sacrificial structure 42 can be used to increase the deformation resistance of the ductile structure 41, that is, to improve the strength of the ductile structure 41 to resist deformation. By means of the sacrificial structure 42, for example, the ductile structure 41 will not be in a cantilever state before encapsulation; thus, the sacrificial structure 42 can limit the distortion of the ductile structure 41 in the lead frame 40, and the ductile structure 41 in the lead frame 40 does not deform before and throughout the encapsulating process.

The lead frame of the present invention can be used in quad flat no lead package (QFN), quad flat package (QFP), dual in-line package (DIP), small outline package (SOP), small outline transistor package (SOT), or system on integrated chip package (SOIC). Besides the aforementioned illustrative examples, the lead frame of the present invention can also be applied to other package structures with lead frame.

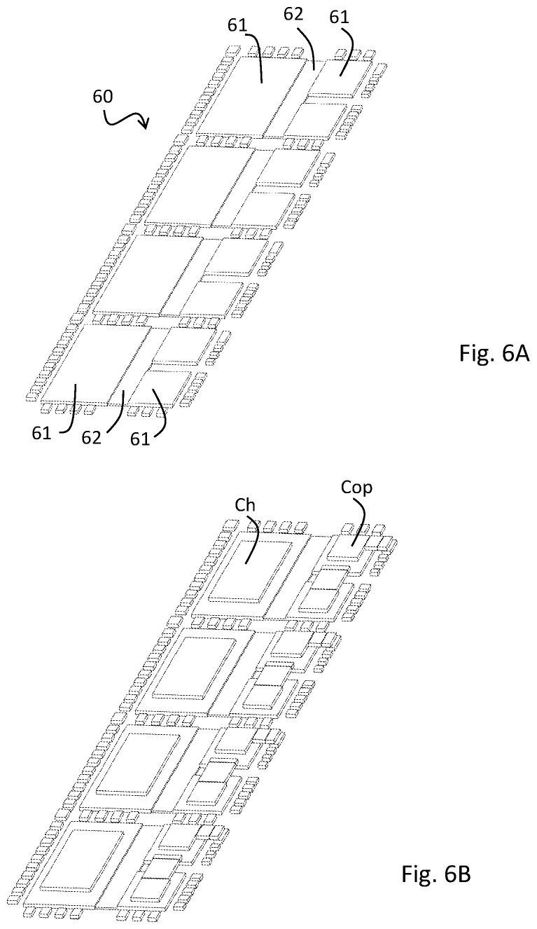

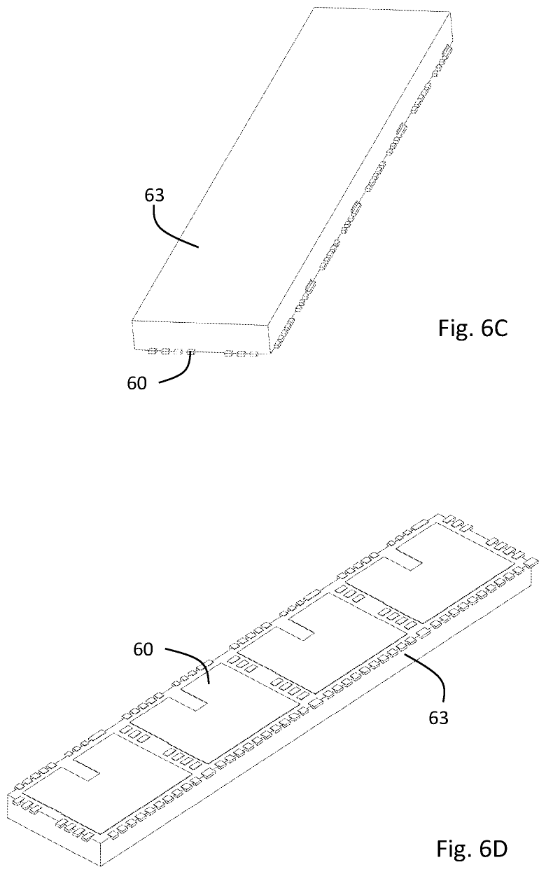

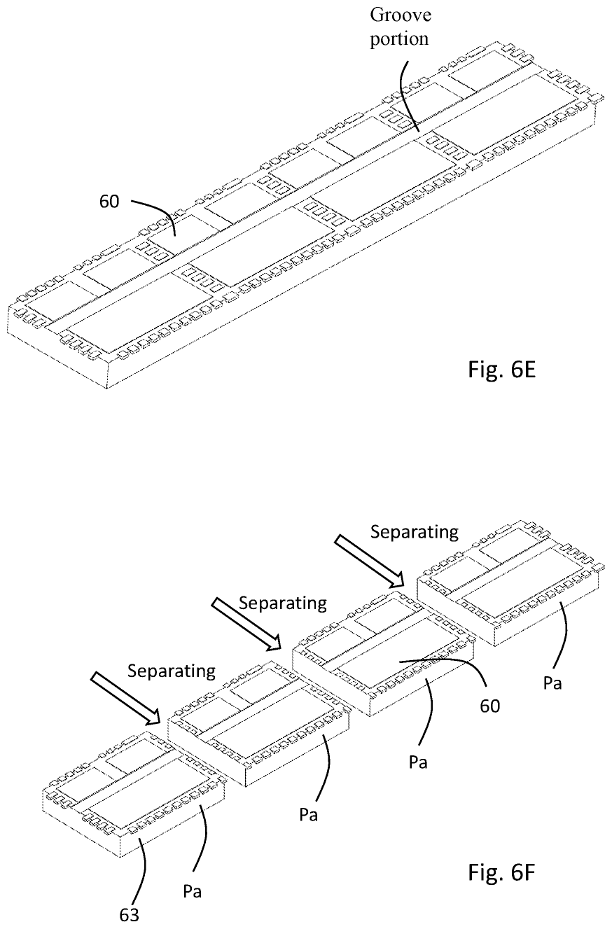

Please refer to FIGS. 6A to 6F, which show a packaging method in one perspective of the present invention. The packaging method includes: providing a lead frame 60 (FIG. 6A), which includes a ductile structure 61 and a sacrificial structure 62, wherein the sacrificial structure 62 is connected between the ductile structure 61 and a near portion of the lead frame 60 for temporarily strengthening the ductile structure 61; disposing a die Ch or a heat dissipation element Cop on the lead frame 60 (FIG. 6B); providing a package material 63 to encapsulate the lead frame 60 and at least one of the die Ch and the heat dissipation element Cop on the lead frame 60 (FIG. 6C shows a top view of the lead frame 60 and the package material 63, and FIG. 6D shows a bottom view of the lead frame 60 and the package material 63); completely cutting off or removing at least one portion of the sacrificial structure 62 from the lead frame 60 (FIG. 6E), thereby forming a groove portion after completely cutting off or removing the sacrificial structure 62; and cutting the package material 63 and the lead frame 60 (FIG. 6F) to form multiple package structures Pa. Each of the package structure Pa includes at least one of the die Ch and the heat dissipation element Cop, a package material portion separated from the package material, and a lead frame portion separated from the lead frame.

In one embodiment, the aforementioned step of disposing the die Ch or the heat dissipation element Cop on the lead frame 60 further includes: providing wirings between the die Ch and the lead frame 60 to create signal communication lines between the die Ch and the lead frame 60.

In one embodiment, the step of encapsulating the lead frame 60 with the die Ch or the heat dissipation element Cop by the package material 63, further includes: encapsulating one side of the lead frame 60 by the package material 63, together with the die Ch or the heat dissipation element Cop on this side of the lead frame 60. Referring to FIGS. 6B and 6C, the die Ch and the heat dissipation element Cop in FIG. 6B are covered by the package material 63 as shown FIG. 6C, and the other side of the lead frame 60 is exposed outside the package material 63. However, the present invention is not limited to the one-side encapsulation as described above; in another embodiment, the package material 63 can encapsulate both sides of the lead frame 60.

In one embodiment, the step of removing the sacrificial structures 42, 52, and 62 from the lead frames 40, 50, and 60, includes: removing the sacrificial structures 42, 52, and 62 by laser cutting, chemical etching, or mechanical machining. In one embodiment, the mechanical machining process may include stamping, cutting, grinding, or other suitable machining processes. The temperature of the package material 63 can be determined according to the method for removing the sacrificial structures 42, 52, and 62. For one example, in chemical etching, the package material 63 can be at a solidified temperature. For another example, in mechanical machining, the package material 63 may be kept at a temperature wherein the package material 63 is not fully in a glassy state in order to avoid excessive residue stress. Alternatively, the package material 63 may be at the solidified temperature in the mechanical machining. In short, the temperature of the package material 63 can be determined according to user's need when removing the sacrificial structures.

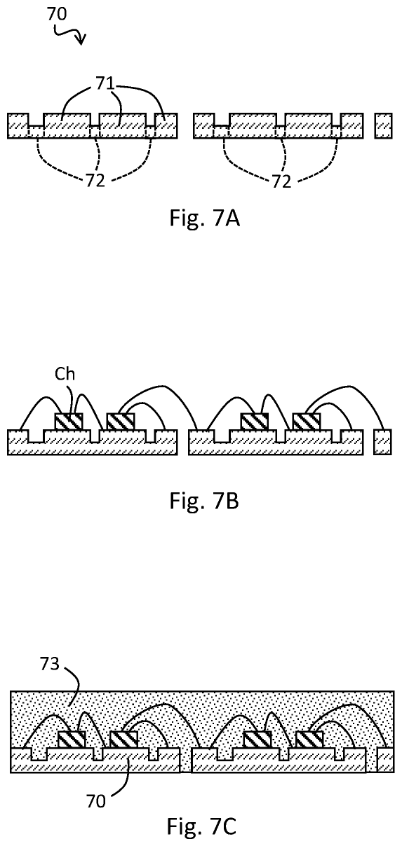

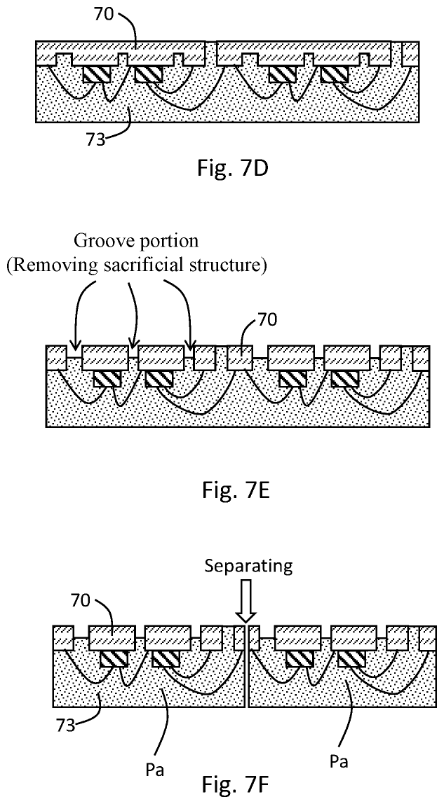

Please refer to FIGS. 7A to 7F for another embodiment of a packaging method according to the present invention. This packaging method includes: providing a lead frame 70 (FIG. 7A), wherein the lead frame 70 includes a ductile structure 71 and a sacrificial structure 72, and the sacrificial structure 72 is connected between the ductile structure 71 and a near portion of the lead frame 70 for temporarily strengthening the ductile structure 71; disposing a die Ch or a heat dissipation element on the lead frame 70 (FIG. 7B shows an example of dispositioning the die Ch and connecting the die Ch and the lead frame 70 by wirings); providing a package material 73 to encapsulate the lead frame 70 and at least one of the die Ch and the heat dissipation element thereon (FIG. 7C shows a top view of the lead frame 70 and the package material 73, and FIG. 7D shows a bottom view of the lead frame 70 and the package material 73); completely cutting off or removing at least one portion of the sacrificial structure 72 from the lead frame 70 (FIG. 7E), wherein a groove portion is formed after completely cutting off or removing the sacrificial structure 72; and cutting the package material 73 and the lead frame 70 (FIG. 7F) to form multiple package structures Pa. Each of the package structure Pa includes at least one of the die Ch and the heat dissipation element Cop, a package material portion separated from the package material, and a lead frame portion separated from the lead frame.

The present invention has been described in considerable detail with reference to certain preferred embodiments thereof. It should be understood that the description is for illustrative purpose, not for limiting the broadest scope of the present invention. An embodiment or a claim of the present invention does not need to achieve all the objectives or advantages of the present invention. The title and abstract are provided for assisting searches but not for limiting the scope of the present invention. Those skilled in this art can readily conceive variations and modifications within the spirit of the present invention. For example, two or more of the embodiments can be used together, or, a part of one embodiment can be used to replace a corresponding part of another embodiment. For another example, the number of die (s) on the lead frame can be different from the number as shown in drawings, the dispositions of the components can be in another arrangement, or the shapes of the components are different from the drawings. In view of the foregoing, the spirit of the present invention should cover all such and other modifications and variations, which should be interpreted to fall within the scope of the following claims and their equivalents.

What is claimed is:

1. A lead frame, including:
at least one ductile structure, which includes a bond area, a die paddle, or a lead finger; and
at least one sacrificial structure, connected between a corresponding one of the at least one ductile structure and a near portion of the lead frame, wherein the near portion is a portion of the lead frame close to the ductile structure.

2. The lead frame according to claim 1, wherein the sacrificial structure in the lead frame has a half-cut state, wherein the sacrificial structure in the half-cut state has a thickness less than a thickness of the lead frame.

3. The lead frame according to claim 1, wherein the lead frame is configured for disposing at least one die or at least one heat dissipation element thereon, wherein after encapsulating the lead frame and at least one of the die and the heat dissipation element on the lead frame by a package material, the sacrificial structure is completely cut off or a portion of the sacrificial structure is removed from the lead frame, to form a plurality of package structures.

4. The lead frame according to claim 1, wherein the near portion of the lead frame further includes another bond area, another die paddle, or another lead finger close to the corresponding ductile structure in the lead frame.

5. The lead frame according to claim 1, wherein the sacrificial structure is configured to increase a deformation resistance of the ductile structure.

6. The lead frame according to claim 1, wherein the lead frame is used in quad flat no lead package (QFN), quad flat package (QFP), dual in-line package (DIP), small outline package (SOP), small outline transistor package (SOT), or system on integrated chip package (SOIC).

7. A packaging method, including:
providing a lead frame, which includes at least one ductile structure and at least one sacrificial structure, wherein the sacrificial structure is connected between a corresponding one of the at least one ductile structure and a near portion of the lead frame, wherein the near portion is a portion of the lead frame close to the ductile structure;
disposing a die or a heat dissipation element on the lead frame;
providing a package material to encapsulate the lead frame and at least one of the die and the heat dissipation element on the lead frame;
completely cutting off the sacrificial structure or removing a portion of the sacrificial structure from the lead frame; and
cutting the package material and the lead frame to form a plurality of package structures, wherein each of the package structures includes a package material portion, a lead frame portion, and at least one of the die and the heat dissipation element.

8. The packaging method according to claim 7, wherein the sacrificial structure in the lead frame has a half-cut state, wherein the sacrificial structure in the half-cut state has a thickness less than a thickness of the lead frame.

9. The packaging method according to claim 7, wherein the near portion of the lead frame further includes: another bond area, another die paddle, or another lead finger close to the corresponding ductile structure in the lead frame.

10. The packaging method according to claim 7, wherein the sacrificial structure is configured to increase a deformation resistance of the ductile structure.

11. The packaging method according to claim 7, wherein the step of completely cutting off the sacrificial structure or removing a portion of the sacrificial structure from the lead frame includes: completely cutting off the sacrificial structure or removing the portion of the sacrificial structure from the lead frame by laser cutting, chemical etching, or mechanical machining.
